(19) United States
(12) Patent Application Publication
(10) Pub. No.: US 2008/0280390 A1
(43) Pub. Date: Nov. 13, 2008

(54) METHOD OF FABRICATING SEMICONDUCTOR MEMORY DEVICE HAVING SELF-ALIGNED ELECTRODE, RELATED DEVICE AND ELECTRONIC SYSTEM HAVING THE SAME

(75) Inventors: Jung-In KIM, Seoul (KR); Jae-Hee OH, Gyeonggi-do (KR); Jun-Hyok KONG, Seoul (KR); Jae-Hyun PARK, Gyeonggi-do (KR); Kwang-Woo LEE, Jeollabuk-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/045,612

(22) Filed: Mar. 10, 2008

(30) Foreign Application Priority Data
May 9, 2007 (KR) 10-2007-0045164

(51) Int. Cl. H01L 47/00

(52) U.S. Cl. 438/95; 257/E47.005

(57) ABSTRACT

A method of fabricating a semiconductor memory device having a self-aligned electrode is provided. An interlayer insulating layer having a contact hole is formed on a substrate. A phase change pattern partially filling the contact hole is formed. A bit line which includes a bit extension self-aligned to the phase change pattern and crosses over the interlayer insulating layer is formed. The bit extension may extend in the contact hole on the phase change pattern. The bit extension contacts the phase change pattern.

### CROSS-REFERENCE TO RELATED APPLICATION

This application claims the benefit of Korean Patent Application No. 10-2007-0045164, filed May 9, 2007, the disclosure of which is hereby incorporated herein by reference in its entirety.

### BACKGROUND

1. Field of Invention

Exemplary embodiments of the present invention relate generally to semiconductor devices and methods of fabricating the same and, more particularly, to a method of fabricating a semiconductor memory device having an electrode which is self-aligned to a phase change pattern, and the related device.

2. Description of the Related Art

Semiconductor memory devices may be classified into volatile memory devices and non-volatile memory devices. Non-volatile memory devices do not lose data stored therein even if power supply is interrupted. Accordingly, the non-volatile memory devices are widely applied to secondary storage devices of mobile communication systems, portable memory devices and all kinds of digital appliances.

Much effort has been invested to develop novel memory devices having an effective structure for improving integration density as well as non-volatile memory characteristics. Results of such research efforts have yielded phase change memory devices. A unit cell of a phase change memory cell includes an access device and a data storage element which is serially connected to the access device. The data storage element includes a lower electrode electrically connected to the access device and a phase change material layer in contact with the lower electrode. The phase change material layer is a material layer that can be electrically switched between a substantially amorphous state and a substantially crystalline state, or between various resistivity states under the crystalline state, according to the amount of provided current.

When a program current flows through the lower electrode, Joule heat is generated at an interface between the phase change material layer and the lower electrode. Such Joule heat changes a part of the phase change material layer (hereinafter referred to as a “transition volume”) into a substantially amorphous state or a substantially crystalline state. The resistivity of the transition volume in the substantially amorphous state is higher than the resistivity of the transition volume in the substantially crystalline state. As a result, current flowing through the transition volume may be detected in a read mode, thereby determining whether data stored in the phase change material layer of the phase change memory device is a logic “1” or a logic “0.”

The program current should be proportionally increased as the transition volume is increased. In this case, the access device should be designed to have a current drivability which is sufficient to supply the program current. However, the access device occupies a larger area in order to improve the current drivability. In other words, it is advantageous to improve the integration density of the phase change memory device as the transition volume is reduced.

Also, an upper electrode is provided on the phase change material layer. In general, the upper electrode is formed by a photolithography process. However, the photolithography process commonly causes alignment errors. Furthermore, research into extreme reduction of the phase change material layer and the upper electrode is in progress for high integration. For example, a method of forming a phase change material layer in a contact hole formed in an interlayer insulating layer is being studied. In this method, aligning the upper electrode on the phase change material layer is getting more difficult.

The upper electrode may be formed by forming a conductive layer on the phase change material layer, forming a mask pattern on the conductive layer, and anisotropically etching the conductive layer using the mask pattern as an etch mask. When alignment errors occur in the mask pattern, a portion of the phase change material layer that is next to the upper electrode is exposed. In order to remove the cause of current leakage such as micro-bridges, the etching process of the conductive layer commonly uses an over-etch technique. In this case, the exposed phase change material layer is damaged. Damage to the phase change material layer deteriorates electrical characteristics of the phase change memory devices.

There is a method of forming the upper electrode to be large enough in consideration of the alignment error. In this method, however, the upper electrode is an obstacle to the high integration of the phase change memory device.

Meanwhile, another technology for implementing a phase change memory device is disclosed in U.S. Patent Publication No. 2006/0257787, entitled “Multi-Level Phase Change Memory,” by Kuo.

### SUMMARY

One embodiment exemplarily described herein can be generally characterized as providing a method of fabricating a semiconductor memory device which is favorable for high integration and suitable for preventing damage to a phase change pattern.

Another embodiment exemplarily described herein can be generally characterized as providing a semiconductor memory device which is favorable for high integration and suitable for preventing damage to phase change pattern.

Still another embodiment exemplarily described herein can be generally characterized as providing a semiconductor memory device which is favorable for high integration and suitable for preventing damage to the phase change pattern.

One embodiment exemplarily described herein can be generally characterized as a method of fabricating a semiconductor memory device. The method may include forming an interlayer insulating layer having a plurality of contact holes on a substrate; forming a plurality of phase change patterns, wherein each of the plurality of phase change patterns partially fills a corresponding one of the plurality of contact holes; and forming a bit line over the interlayer insulating layer, the bit line including a bit extension that is self-aligned with respect to the phase change pattern and that contacts the phase change pattern.

Another embodiment exemplarily described herein can be generally characterized as a method of fabricating a semiconductor memory device. The method may include forming a middle insulating layer having a middle contact hole on a substrate; forming a lower electrode in the middle contact hole; forming an upper insulating layer covering the lower electrode and the middle insulating layer; forming an upper contact hole passing through the upper insulating layer on the lower electrode; forming a phase change pattern partially filling the upper contact hole; and forming a bit line over the upper insulating layer, the bit line including a bit extension that is self-aligned with respect to the phase change pattern and that contacts the phase change pattern.

Yet another embodiment exemplarily described herein can be generally characterized as a semiconductor memory device. The semiconductor memory device may include an interlayer insulating layer disposed on a substrate and including a plurality of contact holes; a plurality of phase change patterns, wherein each of the plurality of phase change patterns partially fills a corresponding one of the plurality of contact holes; and a bit line over the interlayer insulating layer, the bit line including a plurality of bit extensions, wherein each of the plurality of bit extensions is self-aligned with respect to a corresponding one of the plurality of phase change patterns and contacts a corresponding one of the plurality of phase change patterns.

Still another embodiment exemplarily described herein can be generally characterized as an electronic system. The electronic system may include a microprocessor; an input/output unit performing data communication with the microprocessor; and a semiconductor memory device performing data communication with the microprocessor. The semiconductor memory device may include an interlayer insulating layer disposed on a substrate and including a plurality of contact holes; a plurality of phase change patterns, wherein each of the plurality of phase change patterns partially fills a corresponding one of the plurality of contact holes; and a bit line over the interlayer insulating layer, the bit line including a plurality of bit extensions, wherein each of the plurality of bit extensions is self-aligned with respect to a corresponding one of the plurality of phase change patterns and contacts a corresponding ones of the plurality of phase change patterns.

### BRIEF DESCRIPTION OF THE DRAWINGS

The foregoing and other features of the embodiments described above will become more apparent from the following more particular description of exemplary embodiments of the invention and the accompanying drawings. The drawings are not necessarily to scale.

FIG. 1 is an equivalent circuit diagram illustrating a portion of a cell array region of a semiconductor memory device according to first to fourth exemplary embodiments;

FIG. 2 is a plan view corresponding to the equivalent circuit diagram in FIG. 1;

FIGS. 3 to 10 are cross-sectional views taken along line I-I′ of FIG. 2, which illustrates a method of fabricating a semiconductor memory device according to a first exemplary embodiment;

FIG. 11A is a cross-sectional view taken along line I-I′ of FIG. 2, which illustrates a semiconductor memory device according to the first exemplary embodiment;

FIG. 11B is a cross-sectional view taken along line II-II′ of FIG. 2, which illustrates a semiconductor memory device according to the first exemplary embodiment;

FIGS. 12 to 16 are cross-sectional views taken along line I-I′ of FIG. 2, which illustrates a method of fabricating a semiconductor memory device according to a second exemplary embodiment;

FIG. 17A is a cross-sectional view taken along line I-I′ of FIG. 2, which illustrates a semiconductor memory device according to the second exemplary embodiment;

FIG. 17B is a cross-sectional view taken along line II-II′ of FIG. 2 which illustrates a semiconductor memory device according to the second exemplary embodiment;

FIG. 18 is a cross-sectional view taken along line I-I′ of FIG. 2 which illustrates a semiconductor memory device and a method of fabricating the same according to the third exemplary embodiment;

FIG. 19 is a cross-sectional view taken along line I-I′ of FIG. 2 which illustrates a semiconductor memory device and a method of fabricating the same according to the fourth exemplary embodiment;

FIG. 20 is an equivalent circuit diagram illustrating a portion of a cell array region of a semiconductor memory device according to a fifth exemplary embodiment;

FIG. 21 is a cross-sectional view illustrating a semiconductor memory device and a method of fabricating the same according to the fifth exemplary embodiment;

FIG. 22 is an equivalent circuit diagram illustrating a part of a cell array region of a semiconductor memory device according to a sixth exemplary embodiment;

FIG. 23 is a cross-sectional view illustrating a semiconductor memory device and a method of fabricating the same according to the sixth exemplary embodiment; and

FIG. 24 is a schematic block diagram of one embodiment of an electronic system employing a semiconductor memory device.

### DETAILED DESCRIPTION

Exemplary embodiments of the present invention will now be described with reference to the accompanying drawings. These embodiments may, however, be realized in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. In addition, when a layer is described to be formed on another layer or on a substrate, it means that the layer may be formed on the other layer or on the substrate, or a third layer may be interposed between the layer and the other layer or the substrate. Like numbers refer to like elements throughout the specification.

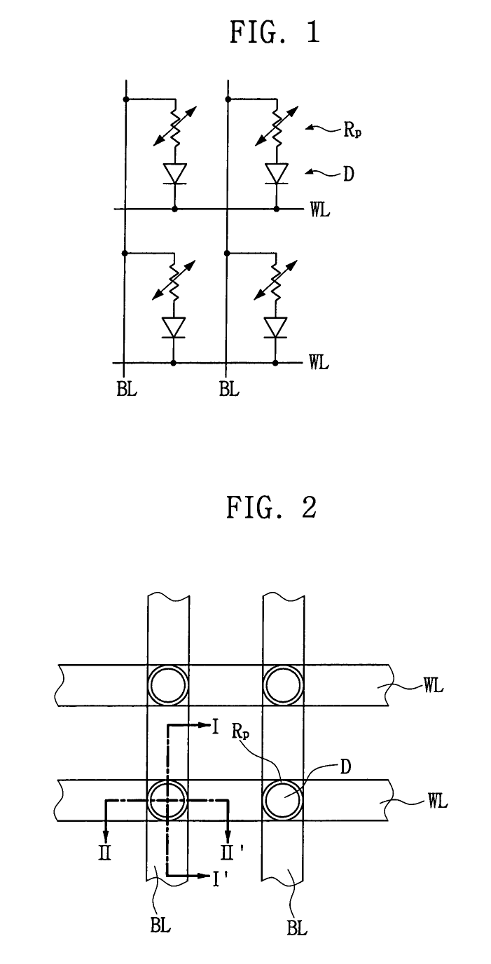

FIG. 1 is an equivalent circuit diagram illustrating a part of a cell array region of a semiconductor memory device according to first to fourth exemplary embodiments. FIG. 2 is a plan view corresponding to the equivalent circuit diagram in FIG. 1.

Referring to FIGS. 1 and 2, the semiconductor memory device according to some exemplary embodiments may include bit lines BL disposed parallel to each other in a column direction, word lines WL disposed parallel to each other in a row direction, a plurality of phase change patterns Rp and a plurality of diodes D.

The bit lines BL may cross the word lines WL. Phase change patterns Rp may be disposed at regions where the bit lines BL and the word lines WL cross each other. Each diode D may be serially connected to a corresponding phase change pattern Rp. Also, each phase change pattern Rp may be connected to a corresponding bit line BL. Each diode D may be connected to a corresponding word line WL. The diode D may serve as an access device. It will be appreciated that the diodes D may be omitted. In another embodiment, the access device may be a MOS transistor.

Methods of fabricating a semiconductor memory device according to a first exemplary embodiment will now be described with reference to FIGS. 2 to 10.

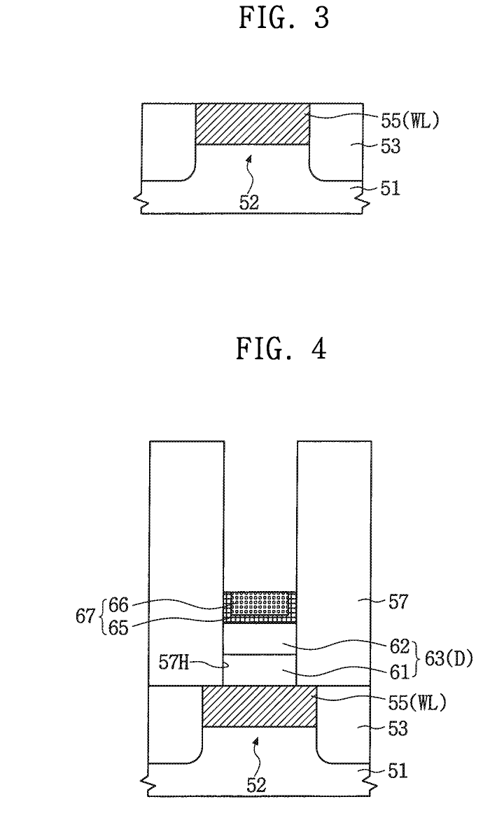

Referring to FIGS. 2 and 3, an isolation layer 53 defining an active region 52 may be formed in a predetermined region of a substrate 51. The substrate 51 may, for example, include semiconductor substrate such as a silicon wafer, a silicon-on-insulator (SOI) wafer, or the like. The substrate 51 may have impurity ions of a first conductivity type. The isolation layer 53 may be formed using a shallow trench isolation (STI) technique, or the like. The isolation layer 53 may, for example, include silicon oxide, silicon nitride, silicon oxynitride, or the like or a combination thereof. The active region 52 may be formed in a line shape.

A word line WL (see FIG. 2) and 55 (see FIG. 3) may be formed by injecting impurity ions of a second conductivity type that is different from the first conductivity type into the active region 52. Hereafter, the first and second conductivity types may be P type and N type, respectively. It will be appreciated, however, that the first and second conductivity types may be N type and P type, respectively.

Referring to FIGS. 2 and 4, an interlayer insulating layer 57 may be formed on the substrate 51 having the word line WL and 55 and the isolation layer 53. The interlayer insulating layer 57 may, for example, include silicon oxide, silicon nitride, silicon oxynitride, or the like or a combination thereof. A contact hole 57H exposing a predetermined region of the word line WL and 55 may be formed by patterning the interlayer insulating layer 57.

First and second semiconductor patterns 61 and 62 may be sequentially stacked in the contact hole 57H. The first and second semiconductor patterns 61 and 62 may be formed using, for example, an epitaxial growth technique or a chemical vapor deposition (CVD) technique. The first and second semiconductor patterns 61 and 62 may constitute a diode D (see FIG. 2) and 63 (see FIG. 4).

The first semiconductor pattern 61 may be in contact with the word line 55(WL). The first semiconductor pattern 61 may be formed to have the impurity ions of the second conductivity type. An upper surface of the second semiconductor pattern 62 may be lower than an upper surface of the interlayer insulating layer 57. Accordingly, the diode 63(D) may be formed in a lower region in the contact hole 57H. The second semiconductor pattern 62 may be formed to have the impurity ions of the first conductivity type. In another embodiment, the first semiconductor pattern 61 may be formed to have the impurity ions of the first conductivity type, and the second semiconductor pattern 62 may be formed to have the impurity ions of the second conductivity type. In one embodiment, a metal silicide layer may be additionally formed on the second semiconductor pattern 62. It will be appreciated, however, that the metal silicide layer may be omitted.

A diode electrode 67 may be formed on the diode 63(D). The diode electrode 67 may include, for example, a Ti layer, a TiSi layer, a TiN layer, TiON layer, a TiW layer, a TiAlN layer, a TiAlON layer, TiSiN layer, a TiBN layer, a W layer, a WN layer, a WON layer, a WSiN layer, a WBN layer, a WCN layer, a Si layer, a Ta layer, a TaSi layer, a TaN layer, a TaON layer, a TaAlN layer, a TaSiN layer, a TaCN layer, a Mo layer, a MoN layer, a MoSiN layer, a MoAlN layer, an NbN layer, a ZrSiN layer, a ZrAlN layer, a Ru layer, a CoSi layer, a NiSi layer, a conductive carbon material layer, a Cu layer, or the like or a combination thereof. For example, the diode electrode 67 may be formed by sequentially stacking a TiN layer 65 and a W layer 66.

The diode electrode 67 may be formed in the contact hole 57H. In one embodiment, the upper surface of the diode electrode 67 may be lower level than the upper surface of the interlayer insulating layer 57. Accordingly, the diode electrode 67 may be self-aligned with respect to the diode 63(D). It will be appreciated, however, that the diode electrode 67 may be omitted.

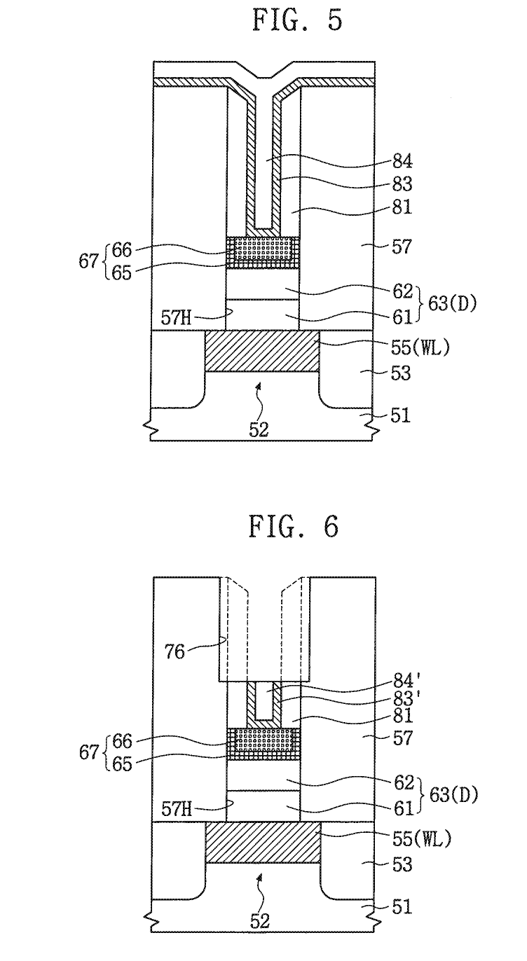

Referring to FIGS. 2 and 5, a contact spacer 81 may be formed on a sidewall of the contact hole 57H. The contact spacer 81 may include a material having an etch selectivity with respect to the interlayer insulating layer 57. Accordingly, the contact spacer 81 may include silicon oxide, silicon nitride, silicon oxynitride, or the like or a combination thereof. As a result, the contact hole 57H may become narrower due to the contact spacer 81. In one embodiment, the upper surface of the diode electrode 67 may be partially exposed in the contact hole 57H. However, when the diode electrode 67 is omitted, the upper surface of the diode 63(D) may be partially exposed in the contact hole 57H. It will be appreciated, however, that the contact spacer 81 may be omitted.

A lower electrode layer 83 may be formed along a surface of the substrate 51. The lower electrode layer 83 may cover the diode electrode 67 in the contact hole 57H, or may be formed to cover the contact spacer 81 and the interlayer insulating layer 57.

The lower electrode layer 83 may, for example, include a Ti layer, a TiSi layer, a TiN layer, a TiON layer, a TiW layer, a TiAlN layer, a TiAlON layer, a TiSiN layer, a TiBN layer, a W layer, a WN layer, a WON layer, a WSiN layer, a WBN layer, a WCN layer, a Si layer, a Ta layer, a TaSi layer, a TaN layer, a TaON layer, a TaAlN layer, a TaSiN layer, a TaCN layer, a Mo layer, a MoN layer, a MoSiN layer, a MoAlN layer, a NbN layer, a ZrSiN layer, a ZrAlN layer, a Ru layer, a CoSi layer, a NiSi layer, a conductive carbon material layer, a Cu layer, or the like or a combination thereof.

A core layer 84 may be formed on the lower electrode layer 83 to fill the contact hole 57H and cover the upper surface of the substrate 51. As a result, a bottom surface of the core layer 84 may be covered by the lower electrode layer 83. The core layer 84 may, for example, include a material having a higher electrical resistance than the lower electrode layer 83. In a further embodiment, the core layer 84 may include an insulating layer such as silicon oxide, silicon nitride, silicon oxynitride, or the like or a combination thereof. In an additional embodiment, the core layer 84 may include a material having an etch selectivity with respect to the interlayer insulating layer 57 and the contact spacer 81. In one embodiment, the core layer 84 may include substantially the same material as the contact spacer 81. For convenience of description, it will be assumed that the core layer 84 and the contact spacer 81 include substantially the same material. In still another embodiment, it will be appreciated that the core layer 84 may be omitted. In such an embodiment, the lower electrode layer 83 may be formed to completely fill the contact hole 57H.

Referring to FIGS. 2 and 6, a lower electrode 83′ and a core pattern 84′ may be formed in the contact hole 57H on the diode electrode 67 by partially removing the core layer 84 and the lower electrode layer 83. For example, the lower electrode 83′ and the core pattern 84′ may be formed using an etch-back process. In another embodiment, the lower electrode 83′ and the core pattern 84′ may be formed using a combination of a chemical mechanical polishing (CMP) process and an etch-back process.

For example, the core layer 84 and the lower electrode layer 83 may be planarized using a CMP process in which the interlayer insulating layer 57 is a stop layer. As a result, portions of the core layer 84 and the lower electrode layer 83 may remain in the contact hole 57H. Then, the portions of the core layer 84 and the lower electrode layer 83 remaining in the contact hole 57H may be recessed downward using an etch-back process such as an isotropic etching process.

While forming the lower electrode 83′ and the core pattern 84′, the contact spacer 81 may also be etched to be recessed downward. Accordingly, the contact spacer 81 may remain between the lower electrode 83′ and the interlayer insulating layer 57.

The lower electrode 83′ may be formed to cover the sidewall and bottom of the core pattern 84′. The lower electrode 83′ may be in contact with the diode electrode 67. When the diode electrode 67 is omitted, the lower electrode 83′ may be in contact with the diode 63(D). The exposed surface of the lower electrode 83′ may be formed in a ring shape. The contact surface between the lower electrode 83′ and the diode electrode 67 may be smaller than an upper surface of the diode electrode 67.

In an embodiment in which the core layer 84 is omitted, the lower electrode 83′ may be formed in a pillar shape.

As a result, the lower electrode 83′ may be self-aligned with respect to the diode electrode 67. The upper surface of the lower electrode 83′ may be lower than the upper surface of the interlayer insulating layer 57.

In one embodiment, an extended contact hole 76 may be formed over the lower electrode 83′ by isotropically etching portions of the interlayer insulating layer 57 exposed in the contact hole 57H. A diameter of the extended contact hole 76 may be greater than a diameter of the contact hole 57H and the extended contact hole 76 may be self-aligned with respect to the contact hole 57H.

Upper surfaces of the core pattern 84′, the lower electrode 83′ and the contact spacers 81 may be exposed by the extended contact hole 76. The upper surfaces of the core pattern 84′, the lower electrode 83′ and the contact spacer 81 may be substantially coplanar. In another embodiment, the upper surface of the lower electrode 83′ may be lower than the upper surface of the core pattern 84′. In yet another embodiment, the upper surface of the contact spacer 81 may be lower than the upper surface of the lower electrode 83′.

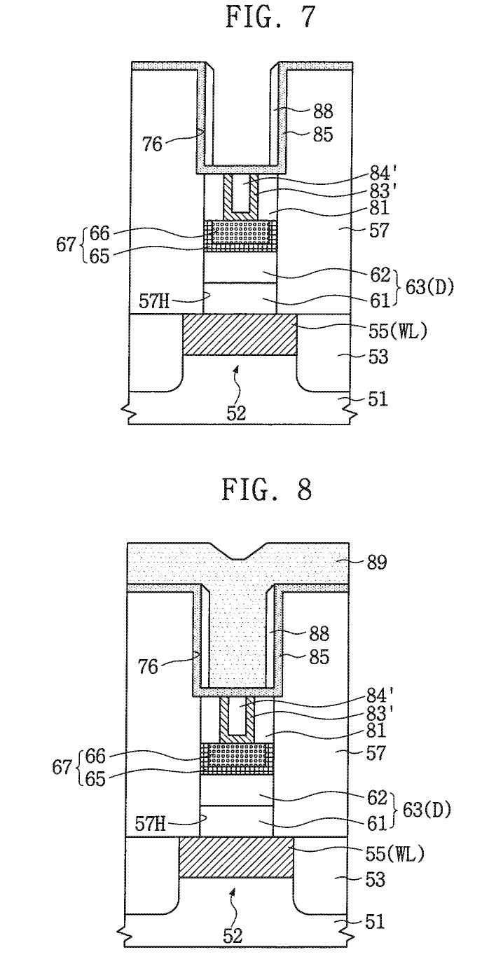

Referring to FIGS. 2 and 7, an interlayer 85 may be formed on the substrate 51 having the extended contact hole 76. The interlayer 85 may be formed to cover an inner wall of the extended contact hole 76 and the upper surface of the interlayer insulating layer 57. The interlayer 85 may cover the lower electrode 83′ and the core pattern 84′ and may include a material such as TiO, ZrO, a conductive carbon material, or the like or a combination thereof.

A capping pattern 88 may be formed on a sidewall of the extended contact hole 76. The capping pattern 88 may, for example, include silicon nitride, silicon oxynitride, silicon oxide, metal oxide, or the like or a combination thereof. For example, the capping pattern 88 may include an aluminum oxide (AlO) layer and a silicon nitride (SiN) layer which are sequentially stacked.

The capping pattern 88 may be formed by forming a capping layer on the interlayer 85 and then anisotropically etching the capping layer until a portion of the interlayer 85 is exposed on the bottom of the extended contact hole 76.

Referring to FIGS. 2 and 8, a phase change material layer 89 may be formed to fill the extended contact hole 76 and covering the upper surface of the substrate 51. The phase change material layer 89 may, for example, include a chalcogenide material. For example, the phase change material layer 89 may include at least two compounds include elements such as Te, Se, Ge, Sb, Bi, Pb, Sn, Ag, As, S, Si, P, O and C. The interlayer 85 may be interposed between the phase change material layer 89 and the lower electrode 83′.

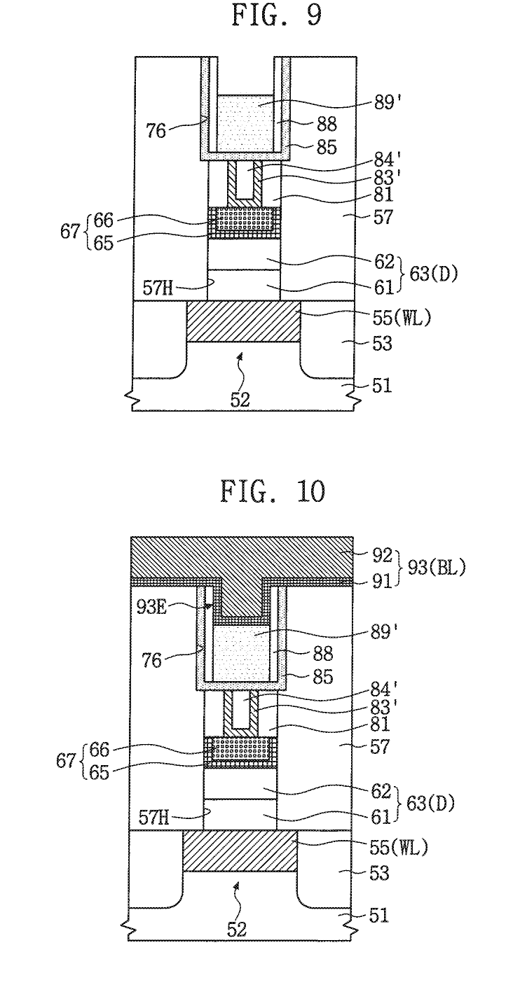

Referring to FIGS. 2 and 9, a phase change pattern Rp (see FIG. 2) and 89′ (see FIG. 9) may be formed in the extended contact hole 76 by partially removing the phase change material layer 89.

For example, the phase change pattern 89′(Rp) may be formed using an etch-back process. In another embodiment, the phase change pattern 89′(Rp) may be formed using a combination of a CMP process and an etch-back process.

For example, the phase change material layer 89 and the interlayer 85 may be planarized using a CMP process in which the interlayer insulating layer 57 is a stop layer. As a result, portions of the phase change material layer 89 and the interlayer 85 may remain in the extended contact hole 76. Then, the portions of the phase change material layer 89 remaining in the extended contact hole 76 may be recessed downward using an etch-back process such as an isotropic etching process. Accordingly, an upper surface of the phase change pattern 89′(Rp) may be lower than the upper surface of the interlayer insulating layer 57. Also, the phase change pattern Rp and 89′ may be self-aligned with respect to the lower electrode 83′.

Referring to FIGS. 2 and 10, a bit line BL (see FIG. 2) and 93 (see FIG. 10) may be formed to contact the phase change pattern 89′(Rp). The bit line 93(BL) may also be formed to cross the word line 55(WL) on the interlayer insulating layer 57.

For example, a bit barrier metal layer and a bit conductive layer may be sequentially stacked on the phase change pattern 89′(Rp) and the interlayer insulating layer 57. The bit conductive layer may be formed to completely fill the extended contact hole 76 and cover the upper surface of the substrate 51. Accordingly, the portion of the bit conductive layer on the phase change pattern 89′(Rp) may be relatively thicker than the portion of the bit conductive layer on the interlayer insulating layer 57. The bit conductive layer and the bit barrier metal layer may then be patterned to form a bit conductive pattern 92 and a bit barrier metal pattern 91. In the illustrated embodiment, the bit conductive pattern 92 and the bit barrier metal pattern 91 may constitute the bit line 93(BL).

The bit conductive pattern 92 may, for example, include a Ti layer, a TiSi layer, a TiN layer, a TiON layer, a TiW layer, a TiAlN layer, a TiAlON layer, a TiSiN layer, a TiBN layer, a W layer, a WN layer, a WON layer, a WSiN layer, a WBN layer, a WCN layer, a Si layer, a Ta layer, a TaSi layer, a TaN layer, a TaON layer, a TaAlN layer, a TaSiN layer, a TaCN layer, a Mo layer, a MoN layer, a MoSiN layer, a MoAlN layer, a NbN layer, a ZrSiN layer, a ZrAlN layer, a Ru layer, a CoSi layer, a NiSi layer, a conductive carbon material layer, a Cu layer, or the like or a combination thereof. The bit barrier metal pattern 91 may be formed of a Ti layer, a TiN layer, a Ta layer, a TaN layer or a combination thereof. However, the bit barrier metal pattern 91 may be omitted.

As a result, the bit line 93(BL) may extend in the extended contact hole 76. That is, a bit extension 93E connected to the bit line 93(BL) may be formed in the extended contact hole 76. The bit extension 93E may be in contact with the phase change pattern 89′(Rp). The bit extension 93E may be self-aligned with respect to the phase change pattern 89′(Rp). The bit extension 93E may serve as an upper electrode.

As exemplarily illustrated in the FIGS., the portion of the bit line 93(BL) on the phase change pattern 89′(Rp) may be substantially thicker than the portion of the bit line 93(BL) on the interlayer insulating layer 57 due to the presence of the bit extension 93E. Accordingly, even if an alignment error caused by photolithography occurs during the formation of the bit line 93(BL), damage to the phase change pattern 89′(Rp) may be prevented.

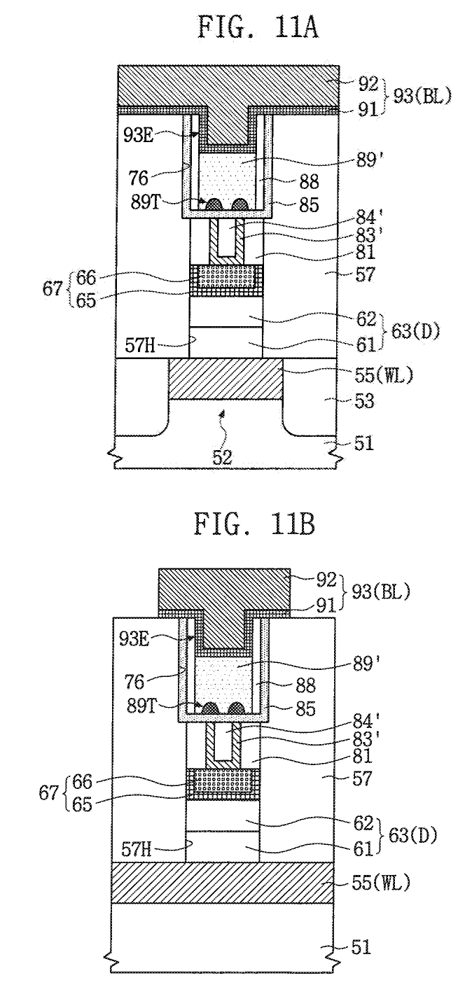

A semiconductor memory device and an operation of the same according to the first exemplary embodiment will now be described below with reference to FIGS. 1, 2, 11A and 11B. FIG. 11A is a cross-sectional view taken along line I-I′ of FIG. 2 and FIG. 11B is a cross-sectional view taken along line II-II′ of FIG. 2, both of which illustrate the semiconductor memory device formed according to the process exemplarily described above with respect to FIGS. 3 to 10. Therefore, only a brief discussion of the semiconductor memory device shown in FIGS. 11A and 11B will be provided below.

Referring to FIGS. 1, 2, 11A and 11B, the semiconductor memory device may include a word line 55(WL) disposed on a substrate 51 and a bit line 93(BL) crossing over the word line 55(WL).

The word line 55(WL) may be defined by an isolation layer 53 disposed in the substrate 51. The substrate 51 may include impurity ions of a first conductivity type. The word line 55(WL) may include impurity ions of a second conductivity type which is different from the first conductivity type.

The substrate 51 having the word line 55(WL) and the isolation layer 53 may be covered with an interlayer insulating layer 57. A contact hole 57H and an extended contact hole 76 may be provided in the interlayer insulating layer 57. The extended contact hole 76 may communicate with an upper region of the contact hole 57H. Also, the extended contact hole 76 may be self-aligned with respect to the upper region of the contact hole 57H. The contact hole 57H and the extended contact hole 76 may extend through the interlayer insulating layer 57.

The first and second semiconductor patterns 61 and 62, which are sequentially stacked in the contact hole 57H, may be provided. The first and second semiconductor patterns 61 and 62 may constitute a diode 63(D). The first semiconductor pattern 61 may be in contact with the word line 55(WL). The first semiconductor pattern 61 may include the impurity ions of the second conductivity type. An upper surface of the second semiconductor pattern 62 may be lower than an upper surface of the interlayer insulating layer 57. Accordingly, the diode 63(D) may be provided in a lower region of the contact hole 57H. The second semiconductor pattern 62 may include the impurity ions of the first conductivity type.

A diode electrode 67 may be disposed on the diode 63(D). The diode electrode 67 may, for example, include a Ti layer, a TiSi layer, a TiN layer, a TiON layer, a TiW layer, a TiAlN layer, a TiAlON layer, a TiSiN layer, a TiBN layer, a W layer, a WN layer, a WON layer, a WSiN layer, a WBN layer, a WCN layer, a Si layer, a Ta layer, a TaSi layer, a TaN layer, a TaON layer, a TaAlN layer, a TaSiN layer, a TaCN layer, a Mo layer, a MoN layer, a MoSiN layer, a MoAlN layer, a NbN layer, a ZrSiN layer, a ZrAlN layer, a Ru layer, a CoSi layer, a NiSi layer, a conductive carbon material layer, a Cu layer, or the like or a combination thereof. For example, the diode electrode 67 may be a TiN layer 65 and a W layer 66 which are sequentially stacked.

The diode electrode 67 may be disposed in the contact hole 57H. Also, an upper surface of the diode electrode 67 may be lower than the upper surface of the interlayer insulating layer 57. Accordingly, the diode electrode 67 may be self-aligned with respect to the diode 63(D). It will be appreciated, however, that the diode electrode 67 may be omitted.

A lower electrode 83′ and a core pattern 84′ may be disposed in the contact hole 57H. The lower electrode 83′ may be disposed to cover the sidewall and bottom of the core pattern 84′. An upper surface of the lower electrode 83′ may be formed in a ring shape. In another embodiment, the core pattern 84′ may be omitted. In such an embodiment, the lower electrode 83′ may be formed in a pillar shape. The lower electrode 83′ may be in contact with an upper surface of the diode electrode 67. When the diode electrode 67 is omitted, however, the lower electrode 83′ may be in contact with an upper surface of the diode 63(D). The lower electrode 83′ may be self-aligned with respect to the diode electrode 67. An upper surface of the lower electrode 83′ may be lower than the upper surface of the interlayer insulating layer 57.

A contact spacer 81 may be interposed between the lower electrode 83′ and the interlayer insulating layer 57. Accordingly, the contact spacer 81 may be disposed on a sidewall of the contact hole 57H. The contact surface between the lower electrode 83′ and the diode electrode 67 may be smaller than the upper surface of the diode electrode 67.

The lower electrode 83′ may, for example, include a Ti layer, a TiSi layer, a TiN layer, a TiON layer, a TiW layer, a TiAlN layer, a TiAlON layer, a TiSiN layer, a TiBN layer, a W layer, a WN layer, a WON layer, a WSiN layer, a WBN layer, a WCN layer, a Si layer, a Ta layer, a TaSi layer, a TaN layer, a TaON layer, a TaAlN layer, a TaSiN layer, a TaCN layer, a Mo layer, a MoN layer, a MoSiN layer, a MoAlN layer, a NbN layer, a ZrSiN layer, a ZrAlN layer, a Ru layer, a CoSi layer, a NiSi layer, a conductive material group layer, a Cu layer, of the like or a combination thereof. The core pattern 84′ may, for example, include a material having a higher electrical resistance than the lower electrode 83′. Furthermore, the core pattern 84′ may include an insulating material such as silicon oxide, silicon nitride, silicon oxynitride, or the like or a combination thereof. Also, the core pattern 84′ may include a material having an etch selectivity with respect to the interlayer insulating layer 57 and the contact spacer 81. Furthermore, the core pattern 84′ and the contact spacer 81 may include substantially the same material.

A phase change pattern 89′(Rp) may be disposed in the extended contact hole 76 on the lower electrode 83′. An upper surface of the phase change pattern 89′(Rp) may be lower than the upper surface of the interlayer insulating layer 57. Also, the phase change pattern 89′(Rp) may be self-aligned with respect to the lower electrode 83′ and may include a chalcogenide material. For example, the phase change pattern 89′(Rp) may include at least two compounds including elements such as Te, Se, Ge, Sb, Bi, Pb, Sn, Ag, As, S, Si, P, O and C.

A capping pattern 88 may be disposed between the phase change pattern 89′(Rp) and the interlayer insulating layer 57 and may cover a sidewall of the extended contact hole 76. The capping pattern 88 may, for example, include silicon nitride, silicon oxynitride, silicon oxide, metal oxide, or the like or a combination thereof. For example, the capping pattern 88 may include an aluminum oxide (AlO) layer and a silicon nitride (SiN) layer which are sequentially stacked.

An interlayer 85 may be disposed between the phase change pattern 89′(Rp) and the lower electrode 83′. The interlayer 85 may cover the lower electrode 83′ and the core pattern 84′. Also, the interlayer 85 may extend between the capping pattern 88 and the interlayer insulating layer 57. The interlayer 85 may, for example, include TiO, ZrO, a conductive carbon material, or the like or a combination thereof. The lower electrode 83′ may be electrically connected to the phase change pattern Rp and 89′ through the interlayer 85. It will be appreciated, however, that the interlayer 85 may be omitted. In such an embodiment, the phase change pattern 89′(Rp) may be in contact with the lower electrode 83′.

The bit line 93(BL) may be disposed on the interlayer insulating layer 57 and may also include a bit extension 93E. The bit extension 93E may extend in the extended contact hole 76 on the phase change pattern 89′(Rp). Accordingly, the bit extension 93E may be self-aligned with respect to the phase change pattern 89′(Rp). The bit extension 93E may be in contact with the phase change pattern 89′(Rp) and may serve as an upper electrode.

The capping pattern 88 may be provided between the bit extension 93E and the interlayer insulating layer 57. The interlayer 85 may remain between the capping pattern 88 and the interlayer insulating layer 57.

The bit line 93(BL) and the bit extension 93E may include a bit barrier metal pattern 91 and a bit conductive pattern 92, which are sequentially stacked. The bit conductive pattern 92 may, for example, include a Ti layer, a TiSi layer, a TiN layer, a TiON layer, a TiW layer, a TiAlN layer, a TiAlON layer, a TiSiN layer, a TiBN layer, a W layer, a WN layer, a WON layer, a WSiN layer, a WBN layer, a WCN layer, a Si layer, a Ta layer, a TaSi layer, a TaN layer, a TaON layer, a TaAlN layer, a TaSiN layer, a TaCN layer, a Mo layer, a MoN layer, a MoSiN layer, a MoAlN layer, a NbN layer, a ZrSiN layer, a ZrAlN layer, a Ru layer, a CoSi layer, a NiSi layer, a conductive carbon material layer, a Cu layer, or the like or a combination thereof. The bit barrier metal pattern 91 may, for example, include a Ti layer, a TiN layer, a Ta layer, a TaN layer, or the like or a combination thereof. It will be appreciated, however, that the bit barrier metal pattern 91 may be omitted.

As illustrated in the FIGS., the bit extension 93E, the phase change pattern 89′(Rp), the interlayer 85, the lower electrode 83′ and the diode electrode 67 may be self-aligned with respect to the diode 63(D). The bit line 93(BL) may be electrically connected to the word line 55(WL) via the bit extension 93E, the phase change pattern 89′(Rp), the interlayer 85, the lower electrode 83′, the diode electrode 67, and the diode 63(D).

When the bit line 93(BL) and the word line 55(WL) are selected and a program current flows through the lower electrode 83′, a part of the phase change pattern 89′(Rp) (hereinafter referred to as a “transition volume 89T”) may be changed into a substantially amorphous or a substantially crystalline state. The transition volume 89T in the substantially amorphous state has a higher resistivity than the transition volume 89T in the substantially crystalline state. Thus, data stored in the phase change pattern 89′(Rp) may be determined as a logic “1” or a logic “0” by detecting the current flowing through the transition volume 89T in a read mode.

The transition volume 89T may have a size and shape corresponding to the upper surface of the lower electrode 83′. When the upper surface of the lower electrode 83′ is formed in a ring shape, the transition volume 89T may also be formed in a ring shape. Accordingly, the size of the transition volume 89T may be relatively low and the transition volume 89T may be changed into the substantially amorphous or substantially crystalline state with only a small amount of program current.

An exemplary method of fabricating a semiconductor memory device according to a second exemplary embodiment will now be described with reference to FIGS. 2 and 12 to 16.

Referring to FIGS. 2 and 12, an isolation layer 53 defining an active region 52 may be formed in a predetermined region of a substrate 51. The active region 52 may be formed in a line shape. A word line 55(WL) may be formed in the active region 52. For the sake of brevity, only differences between the first and second exemplary embodiments will be described.

A lower insulating layer 58 may be formed on the substrate 51 having the word line 55(WL) and the isolation layer 53. The lower insulating layer 58 may, for example, include silicon oxide, silicon nitride, silicon oxynitride, or the like or a combination thereof. A lower contact hole 58H exposing a predetermined region of the word line WL and 55 may be formed by patterning the lower insulating layer 58.

First and second semiconductor patterns 61 and 62 may be sequentially stacked in the lower contact hole 58H. The first and second semiconductor patterns 61 and 62 may constitute a diode 63(D). The diode 63(D) may be formed in a lower region of the lower contact hole 58H. A diode electrode 67 may be formed on the diode 63(D). The diode electrode 67 may be self-aligned with respect to the diode 63(D). Upper surfaces of the diode electrode 67 and the lower insulating layer 58 may be substantially coplanar.

It will be appreciated, however, that the diode electrode 67 may be omitted. In such an embodiment, upper surfaces of the second semiconductor pattern 62 and the lower insulating layer 58 may be substantially coplanar.

The diode electrode 67 may, for example, include a Ti layer, a TiSi layer, a TiN layer, a TiON layer, a TiW layer, a TiAlN layer, a TiAlON layer, a TiSiN layer, a TiBN layer, a W layer, a WN layer, a WON layer, a WSiN layer, a WBN layer, a WCN layer, a Si layer, a Ta layer, a TaSi layer, a TaN layer, a TaON layer, a TaAlN layer, a TaSiN layer, a TaCN layer, a Mo layer, a MoN layer, a MoSiN layer, a MoAlN layer, a NbN layer, a ZrSiN layer, a ZrAlN layer, a Ru layer, a CoSi layer, a NiSi layer, a conductive carbon material layer, a Cu layer, or the like or a combination thereof. For example, the diode electrode 67 may be formed by sequentially stacking a TiN layer 65 and a W layer 66.

A middle insulating layer 71 may be formed on the substrate 51 having the diode electrode 67. The middle insulating layer 71 may, for example, include silicon oxide, silicon nitride, silicon oxynitride, or the like or a combination thereof. A middle contact hole 75′ exposing the diode electrode 67 may be formed by patterning the middle insulating layer 71.

A contact spacer 81 may be formed on a sidewall of the middle contact hole 75′ and may include a material having an etch selectivity with respect to the middle insulating layer 71. As a result, the middle contact hole 75′ may become narrower due to the contact spacer 81. The upper surface of the diode electrode 67 may be partially exposed by the middle contact hole 75′. When the diode electrode 67 is omitted, the upper surface of the diode 63(D) may be partially exposed by the middle contact hole 75′.

A lower electrode layer 83 may be formed along a surface of the substrate 51. The lower electrode layer 83 may cover the diode electrode 67 in the middle contact hole 75′, and the lower electrode layer 83 may be formed to cover the contact spacer 81 and the middle insulating layer 71.

The lower electrode layer 83 may, for example, include a Ti layer, a TiSi layer, a TiN layer, a TiON layer, a TiW layer, a TiAlN layer, a TiAlON layer, a TiSiN layer, a TiBN layer, a W layer, a WN layer, a WON layer, a WSiN layer, a WBN layer, a WCN layer, a Si layer, a Ta layer, a TaSi layer, a TaN layer, a TaON layer, a TaAlN layer, a TaSiN layer, a TaCN layer, a Mo layer, a MoN layer, a MoSiN layer, a MoAlN layer, a NbN layer, a ZrSiN layer, a ZrAlN layer, a Ru layer, a CoSi layer, a NiSi layer, a conductive carbon material layer, a Cu layer, or the like or a combination thereof.

A core layer 84 filling the middle contact hole 75′ and covering the upper surface of the substrate 51 may be formed on the lower electrode layer 83. As a result, a bottom surface of the core layer 84 may be covered by the lower electrode layer 83. The core layer 84 may include a material having a higher electrical resistance than the lower electrode layer 83. Furthermore, the core layer 84 may include an insulating material such as silicon oxide, silicon nitride, silicon oxynitride, or the like or a combination thereof. Also, the core layer 84 may include a material having an etch selectivity with respect to the middle insulating layer 71 and the contact spacer 81. Furthermore, the core layer 84 and the contact spacer 81 may include substantially the same material. For convenience of description, it is assumed that the core layer 84 and the contact spacer 81 include substantially the same material.

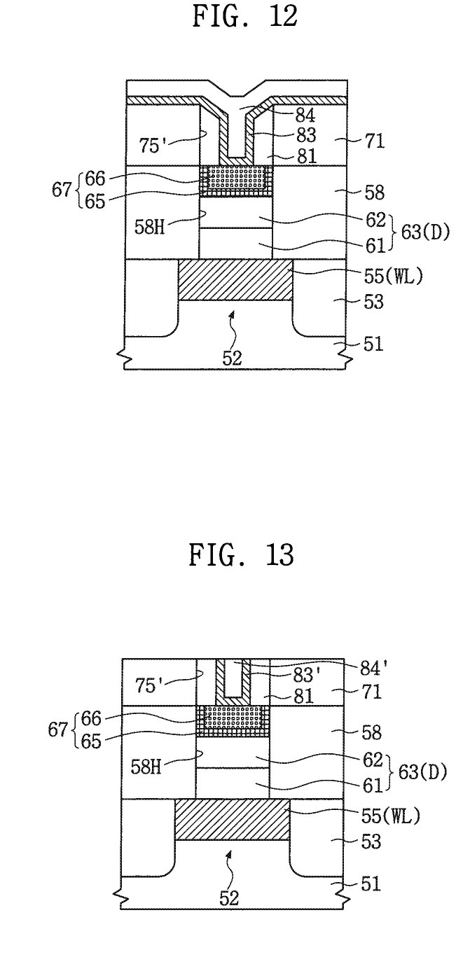

Referring to FIGS. 2 and 13, a core pattern 84′ and a lower electrode 83′ may be formed in the middle contact hole 75′ by planarizing the core layer 84 and the lower electrode layer 83. The lower electrode 83′ and the core pattern 84′ may be formed using, for example, a CMP process, an etch-back process or a combination thereof. For example, the core layer 84 and the lower electrode layer 83 may be planarized using the CMP process in which the middle insulating layer 71 in a stop layer.

The lower electrode 83′ may cover the sidewall and bottom of the core pattern 84′. The lower electrode 83′ may be in contact with the diode electrode 67. When the diode electrode 67 is omitted, the lower electrode 83′ may be in contact with the diode 63(D). The exposed surface of the lower electrode 83′ may be formed in a ring shape. The contact surface between the lower electrode 83′ and the diode electrode 67 may be smaller than the upper surface of the diode electrode 67. In another embodiment, the core pattern 84′ may be omitted. In this case, the lower electrode 83′ may be formed in a pillar shape.

Upper surfaces of the core pattern 84′, the lower electrode 83′, the contact spacer 81 and the middle insulating layer 71 may be substantially coplanar. In another embodiment, the upper surface of the lower electrode 83′ may be lower than the upper surface of the core pattern 84′.

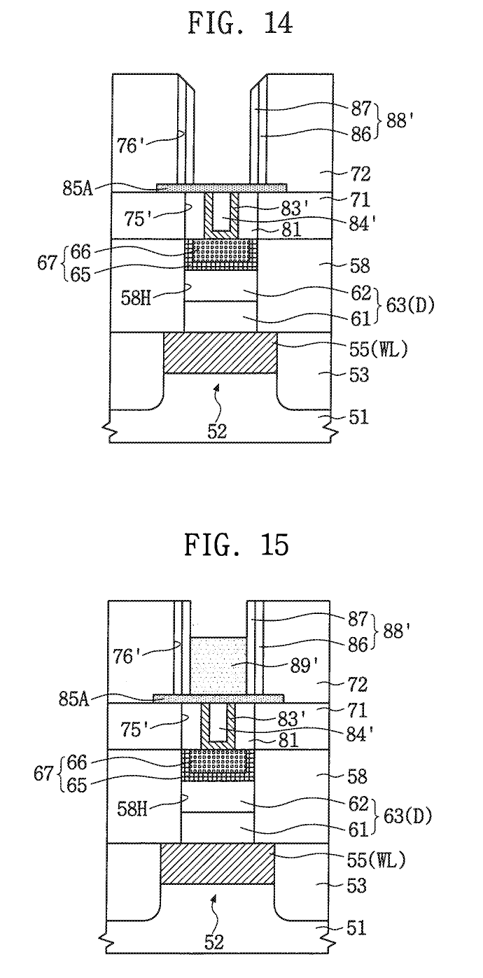

Referring to FIGS. 2 and 14, an interlayer 85A covering the lower electrode 83′ and the core pattern 84′ may be formed on the middle insulating layer 71. The interlayer 85A may be patterned so as to extend along a direction parallel to the word line 55(WL). Accordingly, the middle insulating layer 71 may be exposed at both sides of the interlayer 85A. The interlayer 85A may cover the core pattern 84′, the lower electrode 83′ and the contact spacer 81. The interlayer 85A may, for example, include TiO, ZrO, a conductive carbon material, or the like or a combination thereof. It will be appreciated, however, that the interlayer 85A may be omitted.

An upper insulating layer 72 may be formed on the substrate 51 having the interlayer 85A. The upper insulating layer 72 may, for example, include silicon oxide, silicon nitride, silicon oxynitride, or the like or a combination thereof. An upper contact hole 76′ may be formed by patterning the upper insulating layer 72. The interlayer 85A disposed on the lower electrode 83′ and the core pattern 84′ may be exposed by the upper contact hole 76′. When the interlayer 85A is omitted, the lower electrode 83′ and the core pattern 84′ may be exposed at the bottom of the upper contact hole 76′. The diameter of the upper contact hole 76′ may be larger than the diameter of the middle contact hole 75′.

A capping pattern 88′ may be formed on a sidewall of the upper contact hole 76′. The capping pattern 88′ may, for example, include silicon nitride, silicon oxynitride, silicon oxide, metal oxide, or the like or a combination thereof. For example, the capping pattern 88′ may include an aluminum oxide (AlO) layer 86 and a silicon nitride (SiN) layer 87 which are sequentially stacked.

The capping pattern 88′ may be formed by forming a capping layer covering an upper surface of the substrate 51 followed by anisotropically etching the capping layer until the interlayer 85A is exposed at the bottom of the upper contact hole 76′.

Referring to FIGS. 2 and 15, a phase change pattern 89′(Rp) may be formed to partially fill the upper contact hole 76′. An upper surface of the phase change pattern 89′(Rp) may be lower than an upper surface of the upper insulating layer 72. The phase change pattern 89′(Rp) may include a chalcogenide material. For example, the phase change pattern 89′(Rp) may include at least two compounds including elements such as Te, Se, Ge, Sb, Bi, Pb, Sn, Ag, As, S, Si, P, O and C. The phase change pattern 89′(Rp) may be in contact with the interlayer 85A.

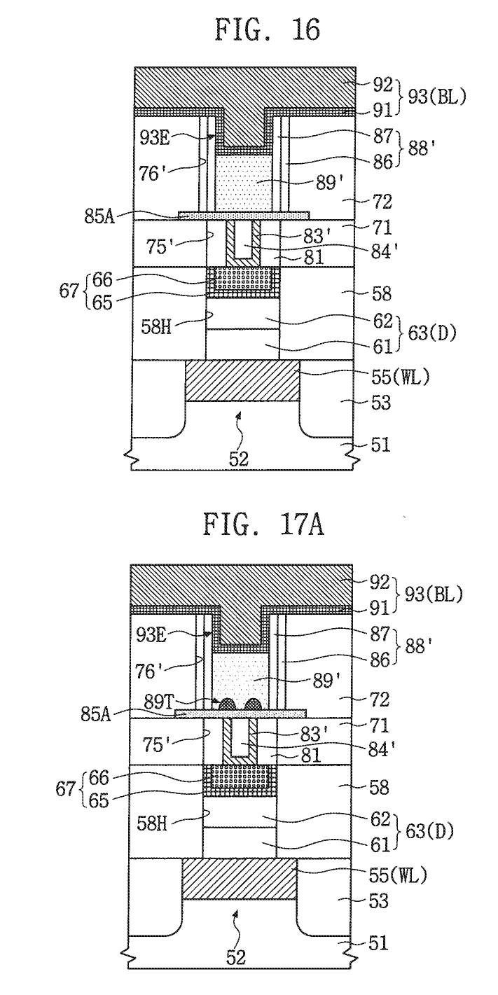

Referring to FIGS. 2 and 16, a bit line 93(BL) may be formed to contact the phase change pattern 89′(Rp). The bit line 93(BL) may be formed to cross the word line 55(WL) on the upper insulating layer 72. The bit line 93(BL) may include a bit barrier metal pattern 91 and a bit conductive pattern 92, which are sequentially stacked.

The bit conductive pattern 92 may, for example, include a Ti layer, a TiSi layer, a TiN layer, a TiON layer, a TiW layer, a TiAlN layer, a TiAlON layer, a TiSiN layer, a TiBN layer, a W layer, a WN layer, a WON layer, a WSiN layer, a WBN layer, a WCN layer, a Si layer, a Ta layer, a TaSi layer, a TaN layer, a TaON layer, a TaAlN layer, a TaSiN layer, a TaCN layer, a Mo layer, a MoN layer, a MoSiN layer, a MoAlN layer, a NbN layer, a ZrSiN layer, a ZrAlN layer, a Ru layer, a CoSi layer, a NiSi layer, a conductive carbon material layer, a Cu layer, or the like or a combination thereof. The bit barrier metal pattern 91 may, for example, include a Ti layer, a TiN layer, a Ta layer, a TaN layer, or the like or a combination thereof. It will be appreciated, however, that the bit barrier metal pattern 91 may be omitted.

The bit line 93(BL) may extend in the upper contact hole 76′. Accordingly, a bit extension 93E connected to the bit line 93(BL) may be formed in the upper contact hole 76′. The bit extension 93E may be in contact with the phase change pattern 89′(Rp). The bit extension 93E may be self-aligned with respect to the phase change pattern 89′(Rp). The bit extension 93E may serve as an upper electrode.

As exemplarily illustrated in the FIGS., the portion of the bit line 93(BL) on the phase change pattern 89′(Rp) may be substantially thicker than the portion of the bit line 93(BL) on the upper insulating layer 72 due to the presence of the bit extension 93E. Accordingly, damage to the phase change pattern 89′(Rp) may be prevented even if an alignment error caused by photolithography occurs during the formation of the bit line 93(BL).

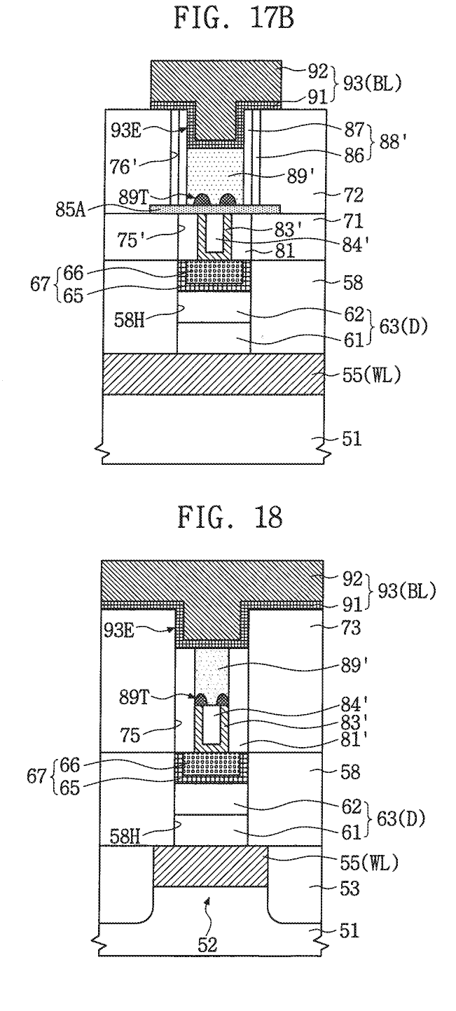

A semiconductor memory device and an operation of the semiconductor memory device according to a second exemplary embodiment of the present invention will now be described with reference to FIGS. 1, 2, 17A and 17B. FIG. 17A is a cross-sectional view taken along line I-I′ of FIG. 2, and FIG. 17B is a cross-sectional view taken along line II-II′ of FIG. 2, both of which illustrate the semiconductor memory device formed according to the process exemplarily described above with respect to FIGS. 12 to 16. Therefore, only a brief discussion of the semiconductor memory device shown in FIGS. 17A and 17B will be provided below.

Referring to FIGS. 1, 2, 17A and 17B, the semiconductor memory device may include a bit extension 93E that is self-aligned with respect to the phase change pattern 89′(Rp). The bit line 93(BL) may be electrically connected to the word line 55(WL) via the bit extension 93E, the phase change pattern 89′(Rp), the interlayer 85A, the lower electrode 83′, the diode electrode 67 and the diode 63(D).

When the bit line 93(BL) and the word line 55(WL) are selected, and a program current flows through the lower electrode 83′, a part of the phase change pattern 89′(Rp) (hereinafter referred to as a “transition volume 89T”) may be changed into a substantially amorphous state or a substantially crystalline state. The transition volume 89T in the substantially amorphous state has a higher resistivity than the transition volume 89T in the substantially crystalline state. Thus, data stored in the phase change pattern 89′(Rp) may be determined as a logic “1” or a logic “0” by detecting the current flowing through the transition volume 89T in a read mode.

The transition volume 89T may have a size and shape corresponding to the upper surface of the lower electrode 83′. When the upper surface of the lower electrode 83′ is formed in a ring shape, the transition volume 89T may also be formed in a ring shape. Accordingly, the size of the transition volume 89T may be relatively low and the transition volume 89T may be changed into the substantially amorphous state or the substantially crystalline state with only a small amount of program current.

An exemplary method of fabricating a semiconductor memory device and the related semiconductor memory device according to a third exemplary embodiment will now be described with reference to FIGS. 2 and 18.

Referring to FIGS. 2 and 18, the semiconductor memory device according to the third exemplary embodiment may include a substrate 51, an isolation layer 53, a word line 55(WL), a lower insulating layer 58, a lower contact hole 58H, a diode 63(D), and a diode electrode 67, which may be formed by the same method as described with reference to FIG. 12. It will be appreciated, however, that the diode electrode 67 may be omitted. In such an embodiment, upper surfaces of the diode 63(D) and the lower insulating layer 58 may substantially coplanar.

An upper insulating layer 73 may be formed on the substrate 51 having the diode electrode 67. An upper contact hole 75 exposing the diode electrode 67 may be formed by patterning the upper insulating layer 73. A contact spacer 81′ may be formed on a sidewall of the upper contact hole 75.

A lower electrode 83′ and a core pattern 84′ may be formed in the upper contact hole 75. The lower electrode 83′ may be formed to cover the sidewall and bottom of the core pattern 84′. The lower electrode 83′ may be in contact with the diode electrode 67. The upper surface of the lower electrode 83′ may be formed in a ring shape. An upper surface of the lower electrode 83′ may be lower than the upper surface of the upper insulating layer 73. A phase change pattern 89′(Rp) partially filling the upper contact hole 75 may be formed on the lower electrode 83′. An upper surface of the phase change pattern 89′(Rp) may be lower than an upper surface of the upper insulating layer 73. The phase change pattern 89′(Rp) may include a chalcogenide material. The phase change pattern 89′(Rp) may be in contact with the lower electrode 83′ and the core pattern 84′. The phase change pattern Rp and 89′ may be self-aligned with respect to the lower electrode 83′.

Subsequently, the contact spacer 81′ may be partially removed using an isotropic etching process. Accordingly, an upper surface of the contact spacer 81′ may be substantially coplanar with, or lower than, an upper surface of the phase change pattern 89′(Rp).

Next, a bit line 93(BL) may be formed to contact with the phase change pattern 89′(Rp). The bit line 93(BL) may include a bit barrier metal pattern 91 and a bit conductive pattern 92, which are sequentially stacked.

The bit line 93(BL) may extend in the upper contact hole 75. Accordingly, a bit extension 93E connected to the bit line 93(BL) may be formed in the upper contact hole 75. The bit extension 93E may be in contact with the phase change pattern 89′(Rp). The bit extension 93E may be self-aligned with respect to the phase change pattern 89′(Rp). The bit extension 93E may serve as an upper electrode.

As exemplarily illustrated in the FIGS., the portion of the bit line 93(BL) disposed on the phase change pattern 89′(Rp) may be substantially thicker than the portion of the bit line 93(BL) disposed on the upper insulating layer 73 due to the bit extension 93E. Accordingly, damage to the phase change pattern 89′(Rp) may be prevented even if an alignment error caused by photolithography occurs during the formation of the bit line 93(BL).

As described above, the phase change pattern 89′(Rp) and the bit extension 93E may be self-aligned with respect to the lower electrode 83′. The bit line 93(BL) may be electrically connected to the word line 55(WL) via the bit extension 93E, the phase change pattern 89′(Rp), the lower electrode 83′, the diode electrode 67, and the diode 63(D).

When the bit line 93(BL) and the word line 55(WL) are selected and a program current flows through the lower electrode 83′, a part of the phase change pattern 89′(Rp) (hereinafter referred to as a “transition volume 89T”) may be changed into a substantially amorphous state or a substantially crystalline state. The transition volume 89T may have a size and shape corresponding to an upper surface of the lower electrode 83′. When the upper surface of the lower electrode 83′ is formed in a ring shape, the transition volume 89T may also be formed in a ring shape. Accordingly, the size of the transition volume 89T may be relatively low and the transition volume 89T may be changed into the substantially amorphous state or the substantially crystalline state with only a small amount of program current.

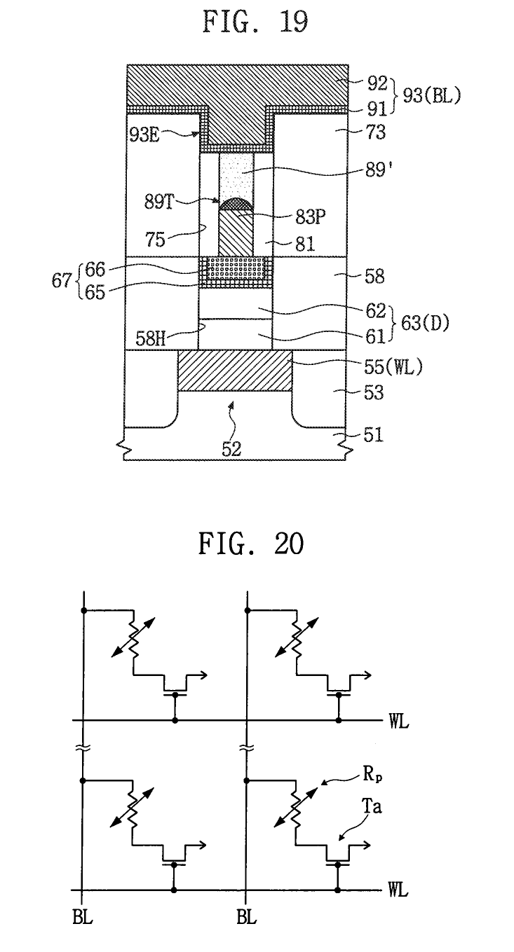

An exemplary method of fabricating a semiconductor memory device and the related semiconductor memory device according to a fourth exemplary embodiment will now be described with reference to FIGS. 2 and 19.

Referring to FIGS. 2 and 19, the semiconductor memory device according to the fourth exemplary embodiment may include a substrate 51, an isolation layer 53, a word line 55(WL), a lower insulating layer 58, a lower contact hole 58H, a diode 63(D), and a diode electrode 67, which may be formed by the same method as illustrated with reference to FIG. 12.

An upper insulating layer 73 may be formed on the substrate 51 having the diode electrode 67. An upper contact hole 75 exposing the diode electrode 67 may be formed by patterning the upper insulating layer 73. A contact spacer 81 may be formed on a sidewall of the upper contact hole 75. A lower electrode 83P may be formed to partially fill the upper contact hole 75. The lower electrode 83P may be in contact with the diode electrode 67. The lower electrode 83P may be formed to have a pillar shape. An upper surface of the lower electrode 83P may be lower than an upper surface of the upper insulating layer 73.

A phase change pattern 89′(Rp) partially filling the upper contact hole 75 may be formed on the lower electrode 83P. An upper surface of the phase change pattern 89′(Rp) may be lower than the upper surface of the upper insulating layer 73, may include a chalcogenide material layer, and may be in contact with the lower electrode 83P.

Subsequently, the contact spacer 81 may be partially removed using an isotropic etching process. Accordingly, an upper surface of the contact spacer 81 may be substantially coplanar with, or lower than, an upper surface of the phase change pattern 89′(Rp).

Next, a bit line 93(BL) may be formed to contact with the phase change pattern 89′(Rp). The bit line 93(BL) may include a bit barrier metal pattern 91 and a bit conductive pattern 92, which are sequentially stacked.

The bit line 93(BL) may extend in the upper contact hole 75. Accordingly, a bit extension 93E connected to the bit line 93(BL) may be formed in the upper contact hole 75. The bit extension 93E may be in contact with the phase change pattern 89′(Rp). The bit extension 93E may be self-aligned with respect to the phase change pattern 89′(Rp). The bit extension 93E may serve as an upper electrode.

As exemplarily illustrated in the FIGS., the portion of the bit line 93(BL) disposed on the phase change pattern 89′(Rp) may be substantially thicker than the portion of the bit line 93(BL) disposed on the upper insulating layer 73 due to the bit extension 93E. Accordingly, damage to the phase change pattern 89′(Rp) may be prevented even if an alignment error caused by photolithography occurs during the formation of the bit line 93(BL).

As described above, the phase change pattern 89′(Rp) and the bit extension 93E may be self-aligned with respect to the lower electrode 83P. The bit line 93(BL) may be electrically connected to the word line 55(WL) via the bit extension 93E, the phase change pattern 89′(Rp), the lower electrode 83P, the diode electrode 67, and the diode 63(D).

When the bit line 93(BL) and the word line 55(WL) are selected and a program current flows through the lower electrode 83P, a part of the phase change pattern 89′(Rp) (hereinafter referred to as a “transition volume 89T”) may be changed into a substantially amorphous state or a substantially crystalline state. The transition volume 89T may have a size and shape corresponding to an upper surface of the lower electrode 83P.

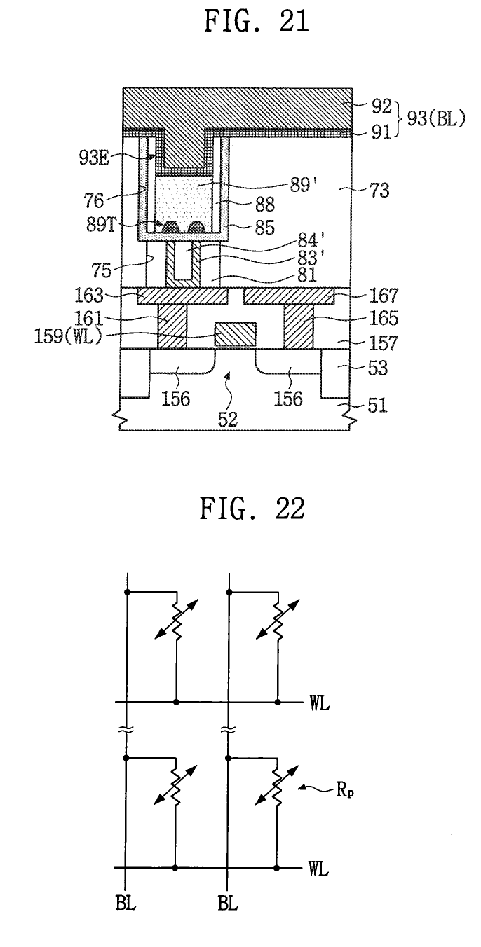

FIG. 20 is an equivalent circuit diagram illustrating a portion of a cell array region of a semiconductor memory device according to a fifth exemplary embodiment. FIG. 21 is a cross-sectional view illustrating a semiconductor memory device and a method of fabricating the same according to the fifth exemplary embodiment.

Referring to FIG. 20, a semiconductor memory device according to a fifth exemplary embodiment may include bit lines BL disposed parallel to each other in a column direction, word lines WL disposed parallel to each other in a row direction, a plurality of phase change patterns Rp, and a plurality of transistors Ta.

The bit lines BL may cross the word lines WL. Phase change patterns Rp may be disposed at regions where the bit lines BL and the word lines WL cross. Each phase change pattern Rp may be serially connected to a corresponding source/drain region of a corresponding transistor Ta. Also, each phase change pattern Rp may be in contact with a corresponding bit line BL. Each transistor Ta may be in contact with a corresponding word line WL. The transistor Ta may serve as an access device. It will be appreciated, however, that the transistors Ta may be omitted. In another embodiment, the access device may be a diode.

Referring to FIG. 21, an isolation layer 53 defining an active region 52 may be formed in a substrate 51. A word line 159(WL) may be formed on the active region 52. Source and drain regions 156 may be formed in the active region 52 adjacent to both sides of the word line 159(WL). A lower insulating layer 157 may be formed to cover the substrate 51 and the word line 159(WL). The word line 159(WL), the active region 52, and the source and drain regions 156 may constitute the transistor Ta shown in FIG. 20.

First and second plugs 161 and 165, respectively, may be formed in the lower insulating layer 157. A drain pad 163 may be formed on the first plug 161 and a source line 167 may be formed on the second plug 165. Upper surfaces of the lower insulating layer 157, the drain pad 163, and the source line 167 may be substantially coplanar. The drain pad 163 may be electrically connected to one of the source and drain regions 156 via the first plug 161, which extends through the lower insulating layer 157. The source line 167 may be electrically connected to the other of the source and drain regions 156 via the second plug 165, which extends though the lower insulating layer 157.

An upper insulating layer 73 may be formed on the lower insulating layer 157. A contact hole 75 exposing the drain pad 163 may be formed by patterning the upper insulating layer 73. A contact spacer 81 may be formed on a sidewall of the contact hole 75. A lower electrode 83′ and a core pattern 84′ may be formed in the contact hole 75. The lower electrode 83′ may be formed to cover the sidewall and bottom of the core pattern 84′. The lower electrode 83′ may be in contact with the drain pad 163. The upper surface of the lower electrode 83′ may be formed in a ring shape. An upper surface of the lower electrode 83′ may be lower than the upper surface of the upper insulating layer 73.

During the formation of the lower electrode 83′ and the core pattern 84′, the contact spacer 81 may also be etched to be recessed downward. Accordingly, the contact spacer 81 may remain between the lower electrode 83′ and the interlayer insulating layer 57.

An extended contact hole 76 may be formed on the lower electrode 83′ by isotropically etching the portion of the upper insulating layer 73 exposed to the contact hole 75. The diameter of the extended contact hole 76 may be larger than the diameter of the contact hole 75. The extended contact hole 76 may be self-aligned with respect to the contact hole 75. Upper surfaces of the core pattern 84′, the lower electrode 83′, and the contact spacer 81 may be exposed in the extended contact hole 76. The upper surfaces of the core pattern 84′, the lower electrode 83′, and the contact spacer 81 may be substantially coplanar.

An interlayer 85 may be formed on the substrate 51 having the extended contact hole 76. The interlayer 85 may be formed to cover an inner wall of the extended contact hole 76, and may cover the lower electrode 83′ and the core pattern 84′. A capping pattern 88 covering the interlayer 85 may be formed on a sidewall of the extended contact hole 76.

A phase change pattern 89′(Rp) partially filling the extended contact hole 76 may be formed on the lower electrode 83′. An upper surface of the phase change pattern 89′(Rp) may be lower than an upper surface of the upper insulating layer 73. The phase change pattern 89′(Rp) may include a chalcogenide material. The phase change pattern 89′(Rp) may be in contact with the interlayer 85. The phase change pattern 89′(Rp) may be self-aligned with respect to the lower electrode 83′.

A bit line 93(BL) may be formed to contact with the phase change pattern 89′(Rp). The bit line 93(BL) may include a bit barrier metal pattern 91 and a bit conductive pattern 92, which are sequentially stacked. It will be appreciated, however, that the bit barrier metal pattern 91 may be omitted.

The bit line 93(BL) may extend in the extended contact hole 76. Accordingly, a bit extension 93E connected to the bit line 39(BL) may be formed in the extended contact hole 76. The bit extension 93E may be in contact with the phase change pattern 89′(Rp). The bit extension 93E may be self-aligned with respect to the phase change pattern 89′(Rp). The bit extension 93E may serve as an upper electrode.

As exemplarily described above, the phase change pattern 89′(Rp) and the bit extension 93E may be self-aligned with respect to the lower electrode 83′. The bit line 93(BL) may be electrically connected to one of the source and drain regions 156 via the bit extension 93E, the phase change pattern 89′(Rp), the interlayer 85, the lower electrode 83′, the drain pad 163, and the first plug 161.

When the bit line 93(BL) and the word line 159(WL) are selected, and a program current flows through the lower electrode 83′, a part of the phase change pattern 89′(Rp) (hereinafter referred to as a “transition volume 89T”) may be changed into a substantially amorphous state or a substantially crystalline state. The transition volume 89T may have a size and shape corresponding to an upper surface of the lower electrode 83′.

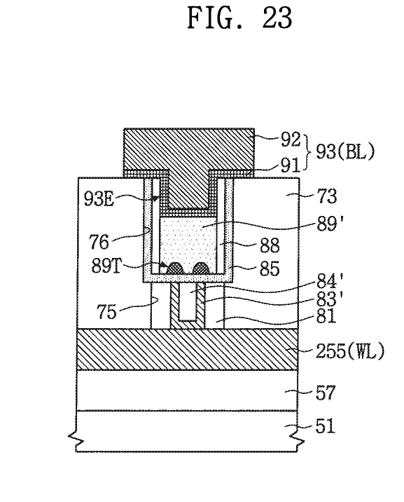

FIG. 22 is an equivalent circuit diagram illustrating a portion of a cell array region of a semiconductor memory device according to a sixth exemplary embodiment. FIG. 23 is a cross-sectional view illustrating a semiconductor memory device and a method of fabricating the same according to the sixth exemplary embodiment.

Referring to FIG. 22, the semiconductor memory device according to the sixth exemplary embodiment may include bit lines BL disposed parallel to each other in a column direction, word lines WL disposed parallel to each other in a row direction, and a plurality of phase change patterns Rp.

The bit lines BL may be disposed to cross the word lines WL. Phase change patterns Rp may be disposed at regions where the bit lines BL and the word lines WL cross each other. One end of each phase change pattern Rp may be connected to a corresponding bit line BL and another end of each phase change pattern Rp may be connected to a corresponding word line WL.

Referring to FIG. 23, a lower insulating layer 57 may be formed on a substrate 51. A word line 255(WL) may be formed in the lower insulating layer 57. The word line 255(WL) may include a conductive interconnection. Upper surfaces of the word line 255(WL) and the lower insulating layer 57 may be substantially coplanar.

An upper insulating layer 73 may be formed to cover the lower insulating layer 57 and the word line 255(WL). A contact hole 75 partially exposing the word line 255(WL) may be formed by patterning the upper insulating layer 73. A contact spacer 81 may be formed on a sidewall of the contact hole 75.

A lower electrode 83′ and a core pattern 84′ may be formed in the contact hole 75. The lower electrode 83′ may be formed to cover the sidewall and bottom of the core pattern 84′. The lower electrode 83′ may be in contact with the word line 255(WL). The upper surface of the lower electrode 83′ may be formed in a ring shape. An upper surface of the lower electrode 83′ may be lower than an upper surface of the upper insulating layer 73.

In one embodiment, the contact spacer 81 may be recessed (e.g., etched) downward while the lower electrode 83′ and the core pattern 84′ are formed. In such an embodiment, the contact spacer 81 may remain between the lower electrode 83′ and the interlayer insulating layer 57.

An extended contact hole 76 may be formed on the lower electrode 83′ by isotropically etching portions of the upper insulating layer 73 which are exposed by the contact hole 75. The diameter of the extended contact hole 76 may be larger than the diameter of the contact hole 75. The extended contact hole 76 may be self-aligned with respect to the contact hole 75. Upper surfaces of the core pattern 84′, the lower electrode 83′, and the contact spacer 81 may be exposed in the extended contact hole 76. The upper surfaces of the core pattern 84′, the lower electrode 83′, and the contact spacer 81 may be substantially coplanar.

An interlayer 85 may be formed on the substrate 51 having the extended contact hole 76. The interlayer 85 may be formed to cover an inner wall of the extended contact hole 76. The interlayer 85 may cover the lower electrode 83′ and the core pattern 84′. A capping pattern 88 covering the interlayer 85 may be formed on a sidewall of the extended contact hole 76.

A phase change pattern 89′(Rp) partially filling the extended contact hole 76 may be formed on the lower electrode 83′. An upper surface of the phase change pattern 89′(Rp) may be lower than an upper surface of the upper insulating layer 73. The phase change pattern 89′(Rp) may include a chalcogenide material. The phase change pattern 89′(Rp) may be in contact with the interlayer 85. The phase change pattern 89′(Rp) may be self-aligned with respect to the lower electrode 83′.

A bit line 93(BL) may be formed to contact with the phase change pattern 89′(Rp). The bit line 93(BL) may include a bit barrier metal pattern 91 and a bit conductive pattern 92, which are sequentially stacked. It will be appreciated, however, that the bit barrier metal pattern 91 may be omitted.

The bit line 93(BL) may extend in the extended contact hole 76. Accordingly, a bit extension 93E connected to the bit line 93(BL) may be formed in the extended contact hole 76. The bit extension 93E may be in contact with the phase change pattern 89′(Rp). The bit extension 93E may be self-aligned with respect to the phase change pattern 89′(Rp). The bit extension 93E may serve as an upper electrode.

As described above, the phase change pattern 89′(Rp) and the bit extension 93E may be self-aligned with respect to the lower electrode 83′. The bit line 89′(Rp) may be electrically connected to the word line 255(WL) via the bit extension 93E, the phase change pattern 89′(Rp), the interlayer 85, and the lower electrode 83′.

When the bit line 93(BL) and the word line 255(WL) are selected, and a program current flows through the lower electrode 83′, a part of the phase change pattern 89′(Rp) (hereinafter referred to as a “transition volume 89T”) may be changed into a substantially amorphous state or a substantially crystalline state. The transition volume 89T may have a size and shape corresponding to an upper surface of the lower electrode 83′.

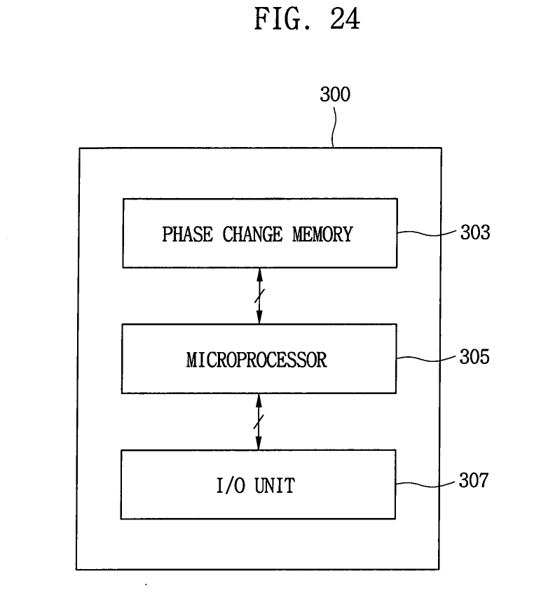

FIG. 24 is a schematic block diagram of one embodiment of an electronic system 300 employing a semiconductor memory device.

Referring to FIG. 24, the electronic system 300 may include a phase change memory device 303 and a microprocessor 305 electrically connected to the phase change memory device 303. The phase change memory device 303 may include one or more of the semiconductor memory devices exemplarily described above with respect to any of FIGS. 1 to 23.

The electronic system 300 may be incorporated within a notebook computer, a digital camera, a mobile phone, or the like. In one embodiment, the microprocessor 305 and the phase change memory device 303 may be mounted on a board and the phase change memory device 303 may serve as data storage media for operating the microprocessor 305.

The electronic system 300 may exchange data with another electronic system such as a personal computer or computer network through an input/output unit 307. The input/output unit 307 may provide data to a peripheral bus line of a computer, a high speed digital transmission line, or wireless transmission/reception antenna. In addition to data communication between the microprocessor 305 and the phase change memory device 303, data communication between the microprocessor 305 and the input/output unit 307 may be performed using common bus architectures.

According to the embodiments exemplarily described above, a bit extension of a bit line is self-aligned with respect to a phase change pattern and the bit line crosses over an interlayer insulating layer. The phase change pattern and the bit extension may be sequentially stacked in a contact hole defined in the interlayer insulating layer. Thus, the portion of the bit line disposed on the phase change pattern may be substantially thicker than the portion of the bit line disposed on the interlayer insulating layer. Accordingly, damage to the phase change pattern may be prevented even if an alignment error caused by photolithography occurs during the formation of the bit line. Consequently, a semiconductor memory device which is favorable for high integration and suitable for preventing damage to the phase change pattern may be realized.

What follows in the paragraphs below is a non-limiting discussion of some exemplary embodiments of the present invention.

In one aspect, some embodiments are directed to a method of fabricating a semiconductor memory device. The method includes forming an interlayer insulating layer having a contact hole on a substrate. A phase change pattern partially filling the contact hole is formed. A bit line including a bit extension self-aligned to the phase change pattern and crossing over the interlayer insulating layer is formed. The bit extension is in contact with the phase change pattern.

In some embodiments of the present invention, a phase change material layer filling the contact hole may be formed. The phase change pattern may be formed by etching-back the phase change material layer to be recessed lower than an upper surface of the interlayer insulating layer. The phase change pattern may be formed of at least two compounds selected from the group consisting of Te, Se, Ge, Sb, Bi, Pb, Sn, Ag, As, S, Si, P, O and C.

In another embodiment, a bit barrier metal layer covering the phase change pattern, a sidewall of the contact hole, and the interlayer insulating layer may be formed. A bit conductive layer completely filling the contact hole and covering the interlayer insulating layer may be formed on the bit barrier metal layer. The bit conductive layer on the phase change pattern may be thicker than the bit conductive layer on the interlayer insulating layer.

In still another embodiment, the contact hole may be extended by etching the interlayer insulating layer prior to the formation of the phase change pattern. A capping pattern may be formed on a sidewall of the extended contact hole. An inter layer may be formed in the extended contact hole prior to the formation of the capping pattern. The inter layer may be formed of one selected from the group consisting of TiO, ZrO, and a conductive carbon group.

In yet another embodiment, a lower electrode may be formed in the contact hole under the phase change pattern prior to the formation of the phase change pattern.

In yet another embodiment, a lower conductive layer covering the sidewall and bottom of the contact hole may be formed. A core layer filling the contact hole may be formed on the lower conductive layer. The lower electrode may be formed by etching-back the lower conductive layer and the core layer. The core layer may be formed of a material layer having a higher electrical resistance than the lower conductive layer.

In yet another embodiment, a contact spacer may be formed on a sidewall of the contact hole prior to the formation of the lower electrode.

In yet another embodiment, a word line may be formed on the substrate prior to the formation of the lower electrode. A diode may be formed in the contact hole between the lower electrode and the word line. A diode electrode may be formed between the diode and the lower electrode. The diode electrode may be formed of one selected from the group consisting of a Ti layer, a TiSi layer, a TiN layer, TiON layer, a TiW layer, a TiAlN layer, a TiAlON layer, a TiSiN layer, a TiBN layer, a W layer, a WN layer, a WON layer, a WSiN layer, a WBN layer, a WCN layer, a Si layer, a Ta layer, a TaSi layer, a TaN layer, a TaON layer, a TaAlN layer, a TaSiN layer, a TaCN layer, a Mo layer, a MoN layer, a MoSiN layer, a MoAlN layer, a NbN layer, a ZrSiN layer, a ZrAlN layer, a Ru layer, a CoSi layer, a NiSi layer, a conductive carbon material layer, a Cu layer, and a combination thereof.

Also, some embodiments are directed to another method of fabricating a semiconductor memory device. The method includes forming a middle insulating layer having a middle contact hole on a substrate. A lower electrode is formed in the middle contact hole. An upper insulating layer covering the lower electrode and the middle insulating layer is formed. An upper contact hole passing through the upper insulating layer on the lower electrode is formed. A phase change pattern partially filling the upper contact hole is formed. A bit line including a bit extension self-aligned to the phase change pattern and crossing over the upper insulating layer is formed. The bit extension is in contact with the phase change pattern.

In some embodiments, a lower conductive layer covering the sidewall and bottom of the middle contact hole and the middle insulating layer may be formed. A core layer may be formed on the lower conductive layer. The lower electrode may be formed by planarizing the lower conductive layer and the core layer. A contact spacer may be formed on a sidewall of the middle contact hole prior to the formation of the lower electrode.

In another embodiment, an inter layer covering the lower electrode may be formed prior to the formation of the upper insulating layer.

In still another embodiment, a word line may be formed on the substrate prior to the formation of the lower electrode. A diode may be formed on the word line. A diode electrode may be formed between the diode and the lower electrode.

In yet another embodiment, a capping pattern may be formed on a sidewall of the upper contact hole prior to the formation of the phase change pattern.

In yet another embodiment, a phase change material filling the upper contact hole may be formed. The phase change pattern may be formed by etching-back the phase change material layer to be recessed lower than an upper surface of the upper insulating layer.

In yet another embodiment, a bit barrier metal layer covering the phase change pattern, the sidewall of the upper contact hole, and the upper insulating layer may be formed. A bit conductive layer completely filling the upper contact hole and covering the upper insulating layer may be formed on the bit barrier metal layer. The bit conductive layer on the phase change pattern may be thicker than the bit conductive layer on the upper insulating layer. The bit line may be formed by partially removing the bit conductive layer and the bit barrier metal layer.

Furthermore, some embodiments are directed to a semiconductor memory device. The device includes an interlayer insulating layer disposed on a substrate. A contact hole is disposed in the interlayer insulating layer. A phase change pattern partially filling the contact hole is provided. A bit line including a bit extension self-aligned to the phase change pattern and crossing over the interlayer insulating layer is provided. The bit extension is in contact with the phase change pattern.

In some embodiments, the bit extension may extend in the contact hole on the phase change pattern. The bit line on the phase change pattern may be thicker than the bit line on the interlayer insulating layer. A capping pattern which is disposed between the phase change pattern and the interlayer insulating layer, and extends between the bit extension and the interlayer insulating layer may be provided.

In another embodiment, a lower electrode may be disposed in the contact hole under the phase change pattern. The phase change pattern may be self-aligned with respect to the lower electrode.

In still another embodiment, a core pattern may be provided in the contact hole under the phase change pattern. In this case, the lower electrode may be disposed to cover the sidewall and bottom of the core pattern. A contact spacer may be disposed between the lower electrode and the interlayer insulating layer.

In yet another embodiment, a word line may be provided on the substrate. A diode may be disposed between the word line and the lower electrode. A diode electrode may be disposed between the diode and the lower electrode. The lower electrode may be self-aligned with respect to the diode.

In yet another embodiment, an inter layer may be disposed between the phase change pattern and the lower electrode.

In yet another embodiment, a transistor electrically connected to the lower electrode may be provided.

Furthermore, some embodiments are directed to an electronic system employing a semiconductor memory device. The electronic system includes a microprocessor, an input/output unit performing data communication with the microprocessor, and a semiconductor memory device performing data communication with the microprocessor. The semiconductor memory device includes an interlayer insulating layer disposed on a substrate. A contact hole is disposed in the interlayer insulating layer. A phase change pattern partially filling the contact hole is provided. A bit line including a bit extension self-aligned to the phase change pattern and crossing over the interlayer insulating layer is provided. The bit extension is in contact with the phase change pattern.

In some embodiments, the bit extension may extend in the contact hole on the phase change pattern. The bit line on the phase change pattern may be thicker than the bit line on the interlayer insulating layer.

Exemplary embodiments have been disclosed herein and, although specific terms are employed, they are used and are to be interpreted in a generic and descriptive sense only and not for purposes of limitation. Accordingly, it will be understood by those of ordinary skill in the art that various changes in form and details may be made without departing from the spirit and scope of the present invention as set forth in the following claims.

What is claimed is:

1. A method of fabricating a semiconductor memory device, comprising:
forming an interlayer insulating layer having a plurality of contact holes on a substrate;
forming a plurality of phase change patterns, wherein each of the plurality of phase change patterns partially fills a corresponding one of the plurality of contact holes; and
forming a bit line over the interlayer insulating layer, the bit line including a bit extension that is self-aligned with respect to the phase change pattern and that contacts the phase change pattern.

2. The method according to claim 1, wherein forming the phase change pattern comprises:
forming a phase change material layer filling the contact hole; and
etching-back the phase change material layer such that an upper surface of the phase change pattern is lower than an upper surface of the interlayer insulating layer.

3. The method according to claim 1, wherein the phase change pattern includes at least two compounds chosen from Te, Se, Ge, Sb, Bi, Pb, Sn, Ag, As, S, Si, P, O and C.

4. The method according to claim 1, wherein forming the bit line comprises:
forming a bit barrier metal layer covering the phase change pattern, a sidewall of the contact hole, and the interlayer insulating layer;
forming a bit conductive layer completely filling the contact hole and covering the interlayer insulating layer on the bit barrier metal layer, wherein a portion of the bit conductive layer over the phase change pattern is thicker than a portion of the bit conductive layer over the interlayer insulating layer; and
partially removing the bit conductive layer and the bit barrier metal layer.

5. The method according to claim 1, further comprising:
before forming the phase change pattern, etching portions of the interlayer insulating layer exposed to the contact hole to form an extended contact hole and forming a capping pattern on a sidewall of the extended contact hole.

6. The method according to claim 5, further comprising:
before forming the capping pattern, forming an interlayer in the extended contact hole.

7. The method according to claim 6, wherein the interlayer includes TiO, ZrO, a conductive carbon group material, or a combination thereof.

8. The method according to claim 1, further comprising:
before forming the phase change pattern, forming a lower electrode in the contact hole.

9. The method according to claim 8, wherein forming the lower electrode comprises:
forming a lower conductive layer covering a sidewall and a bottom of the contact hole;
forming a core layer filling the contact hole on the lower conductive layer; and
etching-back the lower conductive layer and the core layer.

10. The method according to claim 9, wherein the core layer includes a material having a higher electrical resistance than the lower conductive layer.

11. The method according to claim 8, further comprising:
before forming the lower electrode, forming a contact spacer on the sidewall of the contact hole.

12. The method according to claim 8, further comprising:
forming a word line on the substrate;
forming a diode in the contact hole on the word line; and
forming the lower electrode on the diode.

13. The method according to claim 12, further comprising:
forming a diode electrode on the diode; and
forming the lower electrode on the diode electrode.

14. The method according to claim 13, wherein the diode electrode includes Ti, TiSi, TiN, TiON, TiW, TiAlN, TiAlON, TiSiN, TiBN, W, WN, WON, WSiN, WBN, WCN, Si, Ta, TaSi, TaN, TaON, TaAlN, TaSiN, TaCN, Mo, MoN, MoSiN, MoAlN, NbN, ZrSiN, ZrAlN, Ru, CoSi, NiSi, a conductive carbon material, Cu, or a combination thereof.

15. A method of fabricating a semiconductor memory device, comprising:
forming a middle insulating layer having a middle contact hole on a substrate;
forming a lower electrode in the middle contact hole;
forming an upper insulating layer covering the lower electrode and the middle insulating layer;
forming an upper contact hole passing through the upper insulating layer on the lower electrode;
forming a phase change pattern partially filling the upper contact hole; and
forming a bit line over the upper insulating layer, the bit line including a bit extension that is self-aligned with respect to the phase change pattern and that contacts the phase change pattern.

16. The method according to claim 15, wherein forming the lower electrode comprises:
forming a lower conductive layer covering a sidewall and a bottom of the middle contact hole and the middle insulating layer;
forming a core layer on the lower conductive layer; and
planarizing the lower conductive layer and the core layer.

17. The method according to claim 15, further comprising:
before forming the lower electrode, forming a contact spacer on the sidewall of the middle contact hole.

18. The method according to claim 15, further comprising:
before forming the upper insulating layer, forming an interlayer covering an upper surface of the lower electrode.

19. The method according to claim 15, further comprising:
before forming the lower electrode, forming a word line on the substrate and forming a diode on the word line.

20. The method according to claim 19, further comprising:
forming a diode electrode on the diode; and
forming the lower electrode on the diode electrode.

21. The method according to claim 15, further comprising:
before forming the phase change pattern, forming a capping pattern on a sidewall of the upper contact hole.

22. The method according to claim 15, wherein forming the phase change pattern comprises:
forming a phase change material layer filling the upper contact hole; and
etching-back the phase change material layer such than an upper surface of the phase change pattern is lower than an upper surface of the upper insulating layer.

23. The method according to claim 22, wherein forming the bit line comprises:
forming a bit barrier metal layer covering the phase change pattern, a sidewall of the upper contact hole, and the upper insulating layer;
forming a bit conductive layer completely filling the upper contact hole and covering the upper insulating layer on the bit barrier metal layer, wherein a portion of the bit conductive layer over the phase change pattern is thicker than a portion of the bit conductive layer over the upper insulating layer; and
partially removing the bit conductive layer and the bit barrier metal layer.
